(19) United States
(12) Patent Application Publication
(10) Pub. No.: US 2004/0217472 A1
(43) Pub. Date: Nov. 4, 2004

(54) Low cost chip carrier with integrated antenna, heat sink, or EMI shielding functions manufactured from conductive loaded resin-based materials

(75) Inventors: Thomas Aisenbrey, Littleton, CO (US); Thor Arne Larsen, Hopewell Junction, NY (US)

Correspondence Address: STEPHEN B. ACKERMAN, 28 DAVIS AVENUE, POUGHKEEPSIE, NY, 12603, US

(73) Assignee: Integral Technologies, Inc.

(21) Appl. No.: 10/823,099

(22) Filed: Apr. 13, 2004

Related U.S. Application Data
(63) Continuation-in-part of application No. 10/309,429, filed on Dec. 4, 2002.
Application No. 10/309,429 is a continuation-in-part of application No. 10/075,778, filed on Feb. 14, 2002, now Pat. No. 6,741,221.
(60) Provisional application No. 60/462,062, filed on Apr. 14, 2003.
(60) Provisional application No. 60/478,753, filed on Jun. 16, 2003.
(60) Provisional application No. 60/509,791, filed on Oct. 9, 2003.
(60) Provisional application No. 60/519,020, filed on Nov. 10, 2003.
(60) Provisional application No. 60/512,352, filed on Oct. 17, 2003.
(60) Provisional application No. 60/519,673, filed on Nov. 13, 2003.
(60) Provisional application No. 60/269,414, filed on Feb. 16, 2001.
(60) Provisional application No. 60/317,808, filed on Sep. 7, 2001.

(51) Int. Cl. H01L 23/495

(52) U.S. Cl. 257/734; 343/895

(57) ABSTRACT

Chip carrier with integrated functions such as antennas, EMI shields, and heat sinks are formed of a conductive loaded resin-based material. The conductive loaded resin-based material comprises micron conductive powder(s), conductive fiber(s), or a combination of conductive powder and conductive fibers in a base resin host. The ratio of the weight of the conductive powder(s), conductive fiber(s), or a combination of conductive powder and conductive fibers to the weight of the base resin host is between about 0.20 and 0.40. The micron conductive powders are formed from non-metals, such as carbon, graphite, that may also be metallic plated, or from metals such as stainless steel, nickel, copper, silver, that may also be metallic plated, or from a combination of non-metal, plated, or in combination with, metal powders. The micron conductor fibers preferably are of nickel plated carbon fiber, stainless steel fiber, copper fiber, silver fiber, or the like.

This Patent Application claims priority to the U.S. Provisional Patent Application 60/462,062, filed on Apr. 15, 2003, to the U.S. Provisional Patent Application 60/478,753, filed on Jun. 16, 2003, to the U.S. Provisional Patent Application 60/509,791, filed on Oct. 9, 2003, to the U.S. Provisional Patent Application 60/519,020, filed on Nov. 10, 2003, to the U.S. Provisional Patent Application 60/512,352, filed on Oct. 17, 2003, and to the U.S. Provisional Patent Application 60/519,673, filed on Nov. 13, 2003, which are herein incorporated by reference in their entirety.

This Patent Application is a Continuation-in-Part of INT01-002CIP, filed as U.S. patent application Ser. No. 10/309,429, filed on Dec. 4, 2002, also incorporated by reference in its entirety, which is a Continuation-in-Part application of docket number INT01-002, filed as U.S. patent application Ser. No. 10/075,778, filed on Feb. 14, 2002, which claimed priority to US Provisional Patent Applications serial No. 60/317,808, filed on Sep. 7, 2001, serial No. 60/269,414, filed on Feb. 16, 2001, and serial No. 60/317,808, filed on Feb. 15, 2001.

### BACKGROUND OF THE INVENTION

(1) Field of the Invention

This invention relates to integrated circuit chip carriers and, more particularly, to integrated chip carrier functions such as antennas, EMI shields, and heat sinks molded of conductive loaded resin-based materials comprising micron conductive powders, micron conductive fibers, or a combination thereof, homogenized within a base resin when molded. This manufacturing process yields a conductive part or material usable within the EMF or electronic spectrum(s).

(2) Description of the Prior Art

Electronic packaging is one of the greatest challenges facing the semiconductor industry. Packaging allows electrical connection to an integrated circuit while maintaining and regulating its operating environment, performance, and reliability. The primary purpose of an integrated circuit package is to provide a means for electrical connectivity from the semiconductor device to a printed wiring board (PWB) or printed circuit board (PCB). Secondarily, the package houses and protects the IC chip from harsh environmental conditions such as moisture, light, and dust. Finally, the package provides a path for dissipating heat generated by the semiconductor device. The dissipation of heat is one of the major problems in the electronics industry especially for central processing units (CPU), power supplies, and amplifiers.

Commonly, a block of metal is extruded, cast, stamped or machined to form a heat sink. This heat sink is then mechanically attached to the carrier of the integrated circuit using an adhesive or a clipping mechanism. Normally the heat sink is affixed to a protective cap or cover of the integrated circuit carrier to provide the necessary thermal conductivity for cooling the integrated circuit chip. Generally, the heat sink is formed with fins, pins, or posts to provide sufficient area necessary to dissipate the heat via a coolant such as forced air as is well known in the art. The use of discrete heat sinks represents a significant cost in part count, assembly, and tooling for the electronics system.

Cellular phones and satellite-based systems have become very important parts of the electronics industry. The ability to transmit and receive high frequency data is becoming an increasingly important system feature and, further, is becoming a critical area for further up-integration. In particular, discrete transceiving antennas, capable of high frequency operation, require significant space in the assembled system and increase part count, assembly time, and tooling.

Electromagnetic interference (EMI) is another very important consideration in modern electronics systems. The very high switching speeds of modern CPU devices can cause the CPU to generate and/or to radiate EMI energy. This radiated energy can interfere with the performance of the other devices in the electronics system or with other electronics devices nearby the radiating device. Government regulations, such as those enacted by the Federal Communications Commission (FCC), specify maximum radiated emissions for electronics devices. In addition to concern for radiated emissions, the reaction of any given integrated circuit device to the electromagnetic environment must be considered. In response to these demands, system designers must frequently employ EMI shielding techniques to prevent emission, to prevent absorption, or both. A typical technique for EMI shielding is to use a metal shielding can or covering to isolate any device of concern. This shielding can is typically grounded to effectively form a Faraday cage. These techniques can be quite effective. However, the use of discrete metal shielding cans contributes to increased part count, assembly time, and tooling cost.

The integrated circuit chip carrier is a ceramic or plastic device on which the integrated circuit is mounted and encapsulated for environmental protection. Connections from the input/output circuits of the integrated circuit chip or chips mounted on the carrier are made through metallic pads to bonding systems such as wire bonding, tab bonding, or ball bonding to matching metallic pads on the integrated circuit chip carrier. The matching metallic pads are then connected to pins, leads, or connectors that permit the connection of the integrated circuit chip or chips to other circuitry within the system. It is, therefore, a significant object of the present invention is to integrated functions, such as antennas, heat sinks, and/or EMI shielding, onto the chip carrier.

It is well known in the art, that while most of the pins or connectors are metallic, there are examples of pins or connectors that use conductive resin-based materials. A well known instance is the connector system employed in the attachment of control circuitry to liquid crystal displays (LCD). For instance, Shin-Etsu Polymer Co., Ltd. provides a family of flat panel display connectors employing anisotropic conductive polymers. An Example is shown in U.S. Pat. No. 4,431,270 to Funada, et al., which describes lead terminals of a liquid crystal display panel and the terminal pads on a circuit board that are for example polymer type AF elastic connectors of Shin-Etsu Polymer Co., LTD. for connections between the liquid crystal display panel and the circuit board.

The usage of radio frequency (RF) communications is presently steadily increasing in consumer electronic usage. Applications such as RF identification (RFID), cellular telephone, and wireless data networking require small inexpensive antennae. Traditionally these antennae are metal conductors that are embedded in the plastic housing of the cases containing the electronics of the RF devices. U.S. Pat. No. 6,031,492 to Griffin, et al., describes a mobile telephone cradle with a combination antenna and heat sink. The antenna is a dipole antenna that acts as a heat sink for dissipating heat generated at the cradle unit. U.S. Pat. No. 5,771,027 to Marks, et al., describes a composite antenna. The composite antenna has a grid comprised of electrical conductors woven into the warp of a resin reinforced cloth forming one layer of the multi-layer laminate structure of the antenna. U.S. Pat. No. 6,249,261 to Solberg, Jr., et al. details a direction-finding antenna constructed from polymer composite materials that are electrically conductive. The polymer composite materials replace traditional metal materials. U.S. Pat. No. 5,023,624 to Heckaman et al describes a chip carrier package with a cover mounted antenna formed from gold or copper. U.S. Pat. No. 6,582,979 to Coccioli et al shows a leadless chip carrier with an embedded antenna of metal traces.

U.S. Pat. No. 6,377,219 to Smith provides a net-shape molded composite heat exchanger which includes a plurality of thermally conductive fins over-molded onto one end of a metallic heat pipe for use both as an antenna in a cellular telephone and a heat exchanger to dissipate the heat generated within the device. U.S. Pat. No. 6,277,303 to Foulger describes conductive polymer composite materials. The conductive polymer composite material includes a minor phase material that has a semicrystalline polymer and a conductive filler material dispersed in the minor phase material. U.S. Pat. No. 6,368,704 to Murata, et al, provides a conductive paste that exhibits high thermal conductivity (low thermal resistance) after adhesion and hardening, This paste enables an adhesive layer to be thinly formed and provides an electronic part that has excellent radiating capabilities. This enables the reduction of the film's thickness.

In the article by McCluskey, et al, entitled, “Nanocomposite Materials Offer Higher Conductivity and Flexibility”, Proceedings of 3rd International Conference on Adhesive Joining and Coating Technology in Electronics Manufacturing, 1998, pp: 282-286, the mechanical and electrical characteristics of a conductive polymer made with conductive silver flake nanoparticle fillers is described. In the article by Morris, entitled, “Interconnection and assembly of LCD's,” Proceedings Second International Workshop on Active Matrix Liquid Crystal Displays—AMLCDs '95., September 1995, pp: 66-71, interconnections between conductors on the glass LCD cell and the drive electronics are described as having evolved from coarse pitch conductive elastomers to heat seal connectors to anisotropic conductive film bonded tape carrier packages to direct chip attachment.

### SUMMARY OF THE INVENTION

A principal object of the present invention is to provide an effective integrated circuit chip carrier.

A further object of the present invention is to provide a method to form an integrated circuit chip carrier.

A further object of the present invention is to provide a chip carrier with integrated functions molded of conductive loaded resin-based materials.

A yet further object of the present invention is to provide methods to fabricate a chip carrier with integrated functions molded from a conductive loaded resin-based material.

A further object of the present invention is to provide a chip carrier with an integrated antenna molded of conductive loaded resin-based material.

A further object of the present invention is to provide a chip carrier with an integrated heat sink molded of conductive loaded resin-based material.

A further object of the present invention is to provide a chip carrier with an integrated EMI shield molded of conductive loaded resin-based material.

A further object of the present invention is to provide a chip carrier with a combined integrated heat sink and EMI shield molded of conductive loaded resin-based material.

A further object of the present invention is to provide methods to form chip carriers with integrated functions molded of conductive loaded resin-based material where these methods are compatible with a variety of chip carrier types.

In accordance with the objects of this invention, an integrated circuit device is achieved. The device comprises a chip carrier with an integrated circuit die is fixably attached to the chip carrier. An antenna structure is molded onto the chip carrier. This antenna structure comprises a conductive loaded, resin-based material comprising conductive materials in a base resin host.

Also in accordance with the objects of this invention, an integrated circuit device is achieved. The device comprises a chip carrier with an integrated circuit die fixably attached to the chip carrier. Signals on the integrated circuit die are electrically connected to the external leads. An EMI shield is on the chip carrier and comprises a conductive loaded, resin-based material comprising conductive materials in a base resin host.

Also in accordance with the objects of this invention, an integrated circuit device is achieved. The device comprises a chip carrier with an integrated circuit die fixably attached to the chip carrier. Signals on the integrated circuit die are electrically connected to the external leads. A heat sink is on the chip carrier and comprises a conductive loaded, resin-based material comprising conductive materials in a base resin host.

Also in accordance with the objects of this invention, a method to form an integrated circuit device is achieved. The method comprises providing a chip carrier with an integrated circuit die fixably attached to the chip carrier. Signals on the integrated circuit die are electrically connected to the external leads. A conductive loaded, resin-based material comprising conductive materials in a resin-based host is provided. The conductive loaded, resin-based material is molded to form an integrated antenna, heat sink, or EMI shield on the chip carrier.

### BRIEF DESCRIPTION OF THE DRAWINGS

In the accompanying drawings forming a material part of this description, there is shown:

FIGS. 1a and 1b illustrate a first preferred embodiment of the present invention showing a surface mount quad package chip carrier with an integrated circular antenna comprising a conductive loaded resin-based material.

FIG. 2 illustrates a first preferred embodiment of a conductive loaded resin-based material wherein the conductive materials comprise a powder.

FIG. 3 illustrates a second preferred embodiment of a conductive loaded resin-based material wherein the conductive materials comprise micron conductive fibers.

FIG. 4 illustrates a third preferred embodiment of a conductive loaded resin-based material wherein the conductive materials comprise both conductive powder and micron conductive fibers.

FIGS. 5a and 5b illustrate a fourth preferred embodiment wherein conductive fabric-like materials are formed from the conductive loaded resin-based material.

FIGS. 6a and 6b illustrate, in simplified schematic form, an injection molding apparatus and an extrusion molding apparatus that may be used to make chip carriers with integrated functions molded of a conductive loaded resin-based material.

FIGS. 7a and 7b illustrates a second preferred embodiment of the present invention showing a ball grid array chip carrier with an integrated dipole antenna comprising a conductive loaded resin-based material.

FIGS. 8a and 8b illustrates a third preferred embodiment of the present invention showing a ceramic, ball grid array chip carrier with an integrated EMI shield comprising a conductive loaded resin-based material.

FIGS. 9a and 9b illustrates a fourth preferred embodiment of the present invention showing a plastic, ball grid array chip carrier with an integrated EMI shield comprising a conductive loaded resin-based material.

FIG. 10 illustrates a fifth preferred embodiment of the present invention showing a ceramic, ball grid array chip carrier with an integrated EMI shield comprising a conductive loaded resin-based material and including solderable layers for printed wiring board attachment.

FIGS. 11a and 11b illustrates a sixth preferred embodiment of the present invention showing an inverted plastic ball grid array chip carrier with an integrated heat sink comprising a conductive loaded resin-based material.

FIG. 12 illustrates a seventh preferred embodiment of the present invention showing an inverted ball grid array chip carrier with a combined integrated heat sink and EMI shield comprising a conductive loaded resin-based material.

### DESCRIPTION OF THE PREFERRED EMBODIMENTS

This invention relates to chip carriers with integrated functions molded of conductive loaded resin-based materials comprising micron conductive powders, micron conductive fibers, or a combination thereof, homogenized within a base resin when molded.

The conductive loaded resin-based materials of the invention are base resins loaded with conductive materials, which then makes any base resin a conductor rather than an insulator. The resins provide the structural integrity to the molded part. The micron conductive fibers, micron conductive powders, or a combination thereof, are homogenized within the resin during the molding process, providing the electrical continuity.

The conductive loaded resin-based materials can be molded, extruded or the like to provide almost any desired shape or size. The molded conductive loaded resin-based materials can also be cut, stamped, or vacuumed formed from an injection molded or extruded sheet or bar stock, over-molded, laminated, milled or the like to provide the desired shape and size. The thermal or electrical conductivity characteristics of integrated chip carrier functions fabricated using conductive loaded resin-based materials depend on the composition of the conductive loaded resin-based materials, of which the loading or doping parameters can be adjusted, to aid in achieving the desired structural, electrical or other physical characteristics of the material. The selected materials used to fabricate the integrated chip carrier functions are homogenized together using molding techniques and or methods such as injection molding, over-molding, thermo-set, protrusion, extrusion or the like. Characteristics related to 2D, 3D, 4D, and 5D designs, molding and electrical characteristics, include the physical and electrical advantages that can be achieved during the molding process of the actual parts and the polymer physics associated within the conductive networks within the molded part(s) or formed material(s).

The use of conductive loaded resin-based materials in the fabrication of integrated chip carrier functions significantly lowers the cost of materials and the design and manufacturing processes used to hold ease of close tolerances, by forming these materials into desired shapes and sizes. The integrated chip carrier functions can be manufactured into infinite shapes and sizes using conventional forming methods such as injection molding, over-molding, or extrusion or the like. The conductive loaded resin-based materials, when molded, typically but not exclusively produce a desirable usable range of resistivity from between about 5 and 25 ohms per square, but other resistivities can be achieved by varying the doping parameters and/or resin selection(s).

The conductive loaded resin-based materials comprise micron conductive powders, micron conductive fibers, or in any combination thereof, which are homogenized together within the base resin, during the molding process, yielding an easy to produce low cost, electrically conductive, close tolerance manufactured part or circuit. The micron conductive powders can be of carbons, graphites, amines or the like, and/or of metal powders such as nickel, copper, silver, or plated with metals such as nickel, copper, silver, and alloys thereof, or the like. The use of carbons or other forms of powders such as graphite(s) etc. can create additional low level electron exchange and, when used in combination with micron conductive fibers, creates a micron filler element within the micron conductive network of fiber(s) producing further electrical conductivity as well as acting as a lubricant for the molding equipment. The micron conductive fibers can be nickel plated carbon fiber, stainless steel fiber, copper fiber, silver fiber, or the like, or combinations thereof. The structural material is a material such as any polymer resin. Structural material can be, here given as examples and not as an exhaustive list, polymer resins produced by GE PLASTICS, Pittsfield, Mass., a range of other plastics produced by GE PLASTICS, Pittsfield, Mass., a range of other plastics produced by other manufacturers, silicones produced by GE SILICONES, Waterford, N.Y., or other flexible resin-based rubber compounds produced by other manufacturers.

The resin-based structural material loaded with micron conductive powders, micron conductive fibers, or in combination thereof can be molded, using conventional molding methods such as injection molding or over-molding, or extrusion to create desired shapes and sizes. The molded conductive loaded resin-based materials can also be stamped, cut or milled as desired to form create the desired shape form factor(s) of the heat sinks. The doping composition and directionality associated with the micron conductors within the loaded base resins can affect the electrical and structural characteristics of the integrated chip carrier functions, and can be precisely controlled by mold designs, gating and or protrusion design(s) and or during the molding process itself. In addition, the resin base can be selected to obtain the desired thermal characteristics such as very high melting point or specific thermal conductivity.

A resin-based sandwich laminate could also be fabricated with random or continuous webbed micron stainless steel fibers or other conductive fibers, forming a cloth like material. The webbed conductive fiber can be laminated or the like to materials such as Teflon, Polyesters, or any resin-based flexible or solid material(s), which when discretely designed in fiber content(s), orientation(s) and shape(s), will produce a very highly conductive flexible cloth-like material. Such a cloth-like material could also be used in forming integrated chip carrier functions that could be embedded in a person's clothing as well as other resin materials such as rubber(s) or plastic(s). When using conductive fibers as a webbed conductor as part of a laminate or cloth-like material, the fibers may have diameters of between about 3 and 12 microns, typically between about 8 and 12 microns or in the range of about 10 microns, with length(s) that can be seamless or overlapping.

The conductive loaded resin-based material of the present invention can be made resistant to corrosion and/or metal electrolysis by selecting micron conductive fiber and/or micron conductive powder and base resin that are resistant to corrosion and/or metal electrolysis. For example, if a corrosion/electrolysis resistant base resin is combined with stainless steel fiber and carbon fiber/powder, then a corrosion and/or metal electrolysis resistant conductive loaded resin-based material is achieved. Another additional and important feature of the present invention is that the conductive loaded resin-based material of the present invention may be made flame retardant. Selection of a flame-retardant (FR) base resin material allows the resulting product to exhibit flame retardant capability. This is especially important in integrated chip carrier function applications as described herein.

The homogeneous mixing of micron conductive fiber and/or micron conductive powder and base resin described in the present invention may also be described as doping. That is, the homogeneous mixing converts the typically non-conductive base resin material into a conductive material. This process is analogous to the doping process whereby a semiconductor material, such as silicon, can be converted into a conductive material through the introduction of donor/acceptor ions as is well known in the art of semiconductor devices. Therefore, the present invention uses the term doping to mean converting a typically non-conductive base resin material into a conductive material through the homogeneous mixing of micron conductive fiber and/or micron conductive powder into a base resin.

As an additional and important feature of the present invention, the molded conductor loaded resin-based material exhibits excellent thermal dissipation characteristics. Therefore, integrated chip carrier functions manufactured from the molded conductor loaded resin-based material can provide added thermal dissipation capabilities to the application. For example, heat can be dissipated from electrical devices physically and/or electrically connected to structures of the present invention.

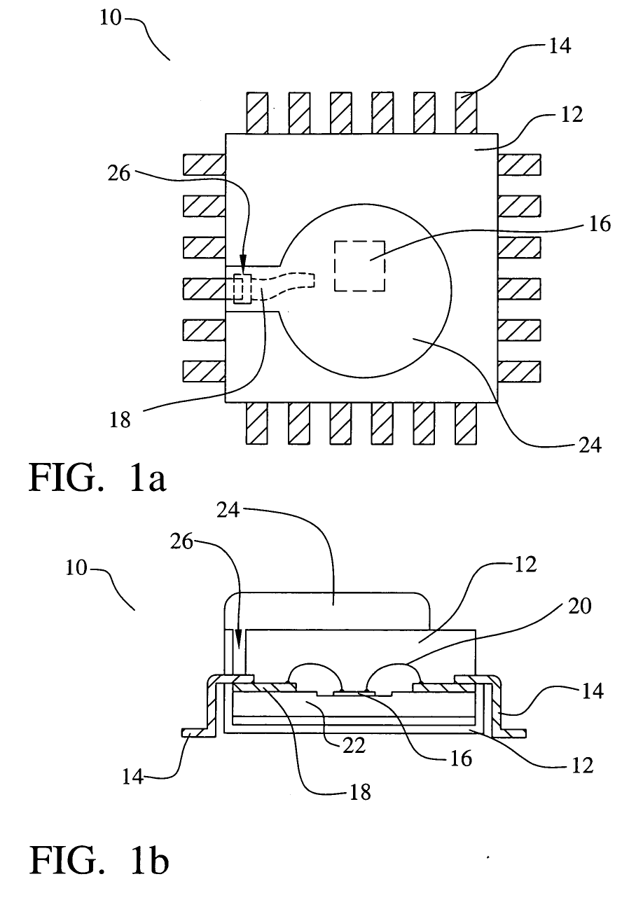

Referring now to FIGS. 1a and 1b, a first preferred embodiment 10 of the present invention is illustrated. Several important features of the present invention are shown. In this embodiment, an antenna function 24 is integrated into a chip carrier 12. In particular, a circular antenna 24 is over-molded onto a chip carrier 12 such that transmission or reception of RF signals can be performed on the integrated circuit device. A surface mount quad package (SMQP) is shown with an integrated circuit die 16 mounted onto a substrate 22 therein. According to methods well known in the art, the integrated circuit die 16 is connected by metal wires 20 to metal traces 18 on the substrate 22. The metal traces 18 further are connected to metal leads 14 to provide external connection of the die 16 to, for example, a printed wiring board (PWB), not shown. Following the wire bonding process, the chip carrier is encapsulated in a resin-based material 12 by a molding operation. The encapsulating layer 12 provides a mechanical and environment barrier to protect the fragile die 16 and wire bonding 20. The encapsulating layer 12 is typically an insulator to prevent electrically shorting of the circuit die 16, wires 20, or traces 18.

As an important and unique feature of the present invention, the encapsulating cover 12 has an opening 26 that exposes a part of the metal interconnect structure 14 and 18. This opening 26 is preferably formed during the molding process for the encapsulating layer 12. After the encapsulating layer 12 has been molded, a second molding operation is performed to over-mold an antenna 24 onto the chip carrier. The antenna 24 comprises a conductive loaded resin-based material according to the teachings of the present invention. The conductive material 24 of the antenna contacts the metal interconnect 14 and 18 of the integrated circuit through the opening 26. The antenna 24 provides a large, conductive surface area for receiving or for transmitting RF signals. It is known that successful RF signal performance is achieved by constructing antennas 24 with dimensions that correspond to even multiple or fractional multiple of wavelengths (λ/4, λ/2, λ, . . . ) of the desired transceiving frequency. In this case, the diameter of the circular antenna disk, or button, 24 is an even multiple or fractional multiple of the desired operating wavelength.

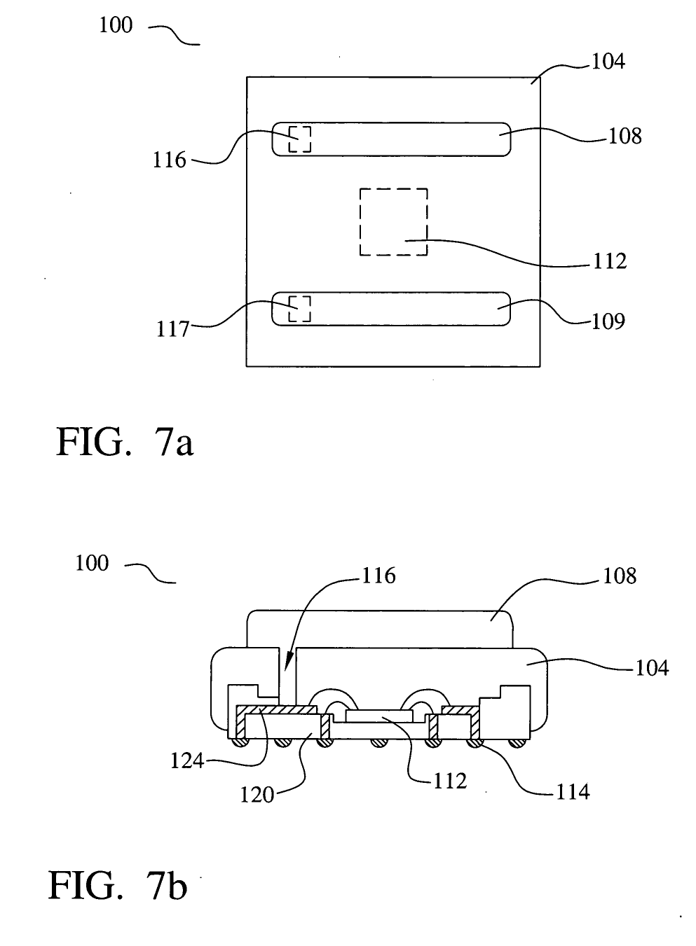

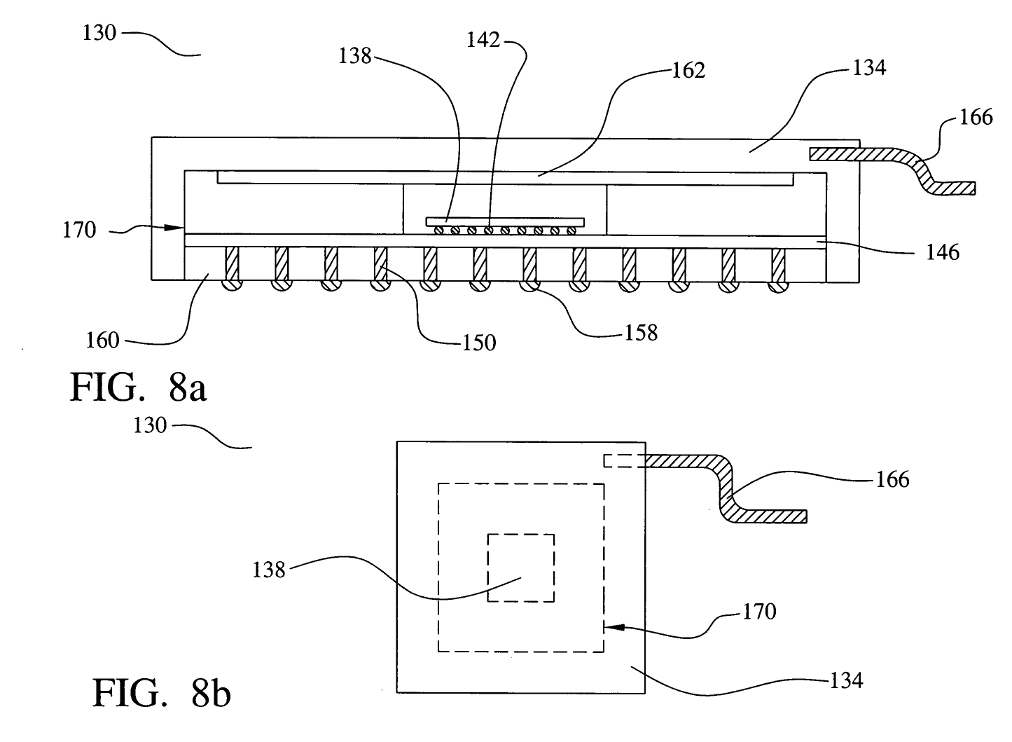

In this example, the chip carrier comprises a surface mount device wherein the leads 14 are formed to mount on the surface of the PWB. Alternatively, this embodiment may be applied to through-hole leaded devices, such as dual in-line packages (DIP), where the leads are formed as vertical pins that stick through the PWB. Alternatively, this embodiment may be applied to surface mount, ball grid array (BGA) packages such as is shown in FIGS. 7a and 7b and is described below. Alternatively, the embodiment may be extended to other types of chip carrier or to multiple IC chip carriers. The substrate 22 of the chip carrier may comprise a ceramic material, a resin-based material, or the like. The die 16 may be connected using metal wire 20, as shown, or, alternatively, by a flip chip method. In a flip chip method, metal bumps are formed on the top surface of the die 16 and then the die 16 is placed, face down, onto the metal traces 18 of the chip carrier to make the connection. An example of a flip chip approach is shown in FIGS. 8a and 8b in the depiction of an EMI shielding integration, however, the method could be used with the antenna integration of FIG. 1. Referring again to FIGS. 1a and 1b, the embodiment depicts a plastic, or resin-based, encapsulating layer 12. Alternatively, a ceramic cover could be used instead. In this case, the conductive loaded resin-based antenna 24 would be over-molded onto the ceramic cover. Preferably, the antenna 24 would be extended such that the conductive loaded resin-based material connects to the exposed lead 14 rather than through a hole in the cover. The integration of the antenna 24 onto the chip carrier facilitates creation of system-on-chip applications and reduces part count, tooling cost, and assembly complexity.

Referring now particularly to FIGS. 7a and 7b, a second preferred embodiment 100 of the present invention is illustrated. In this case, a dipole antenna 108 and 109 is integrated into the chip carrier package. In this case, a ball grid array (BGA) chip carrier is used. The BGA package comprises a substrate 120 having a plurality of metal bumps 114 and metal traces 124 formed thereon. A circuit die 112 is mounted onto the substrate 120 and is wire bonded to the metal traces 124 that provide electrical connection to the ball grid array 114. The BGA carrier is another type of surface mount device where the metal balls 114, or bumps, are soldered to the top surface of a PWB, not shown. Again, an encapsulating layer 104 of resin-based material is molded over the substrate 120 and the circuit die 112. Openings 116 and 117 are formed into the encapsulating layer 104 preferably during the molding process by the mold die design. The antenna 108 and 109 is then over-molded onto the encapsulating layer 104 by molding a conductive loaded resin-based material according to the present invention. The conductive material of the antenna 108 and 109 contacts underlying metal trace(s) 124 through the openings 116 and 117 such that the antenna 108 and 109 is connected to the integrated circuit die 112. Either of the antenna segments 108 and 109 may be the counterpoise. Alternatively, multiple connection points may be created to the underlying chip carrier traces 124 during the encapsulating layer 104 molding to allow the over-molded conductive loaded resin-based material 108 to contact multiple signals on the carrier. For example, multiple contact openings would allow more than one antenna to be molded onto the carrier and connected to the circuit die 112. A dipole antenna 108 is shown, however, any shape of antenna, such as monopole, branching, and the like, may be used.

As an optional but important feature, the conductive loaded resin-based antenna devices of the present invention may be further optimized or tuned using any of, or a combination of, are several methods. For example, A metal layer may be selectively plated onto part of or all of the antenna structure. The plated metal combines with and directly affects the impedance characteristics of the conductive loaded resin-based material to thereby tailor a particular resonance frequency, bandwidth, and/or impedance response, or the like, for the plated antenna. The interactions between antenna and plated layer depend on the type of metal, the plated thickness, and/or the plated pattern, and the like. Alternatively, conductive threads or wires, whether insulated or non-insulated, may be selectively stitched into the antenna structure. This conductive stitching combines with and directly affects the impedance characteristics of the conductive loaded resin-based material to thereby tailor a particular resonance frequency, bandwidth, and/or impedance response, or the like, of the stitched antenna. The placement of the stitches, the presence/absence of an insulator on the threads/wires, and/or the type of stitching material determine the interaction of the stitching and antenna. As yet another alternative, conductive threads or wires, whether insulated or non-insulated, may be selectively embedded, wrapped, and/or center-fused into the antenna structure. The conductive threads or wires included in the antenna structure in this manner combine with and directly affect the impedance characteristics of the conductive loaded resin-based material to thereby tailor a particular resonance frequency, bandwidth, and/or impedance response, or the like, of the wrapped/embedded/fused antenna. The placement of the conductive threads or wires, the presence/absence of an insulator on the threads/wires, and/or the type of thread/wire material determine the interaction of the wire and antenna. Finally, any of these techniques may be combined, such as in using both plating and stitching, to further optimize the performance of the conductive loaded resin-based antenna of the present invention.

Referring now to FIGS. 8a and 8b, a third preferred embodiment 130 of the present invention is illustrated. A chip carrier 130 with an integrated EMI shield is shown. A ceramic, ball grid array (BGA) chip carrier comprises a substrate 160 of ceramic material with an array of metal ball contacts 158 formed thereon. The ball contacts 158 are connected to an interface layer 146 by vertical vias 150. The interface layer 146 comprises horizontal traces, not shown, that terminate as an array underlying the circuit die 138. The integrated circuit die 138 comprises an array of solder bumps 142 formed on the top surface of the die 138. The die 138 is flip chip mounted onto the interface layer 146 such that an electrical connection is made from the solder bumps 142 to the chip carrier balls 158. A lid 162 of ceramic or of metal 162 is attached to the top of the chip carrier 130 to encapsulate the mounted die 138.

As an important feature, an electromagnetic interference (EMI) shielding function 134 is formed over the chip carrier. The EMI shield 134 is formed from conductive loaded resin-based material according to the present invention. Preferably, the EMI shield 134 is molded onto the chip carrier. For example, after the die 138 is attached and bonded and the sealing lid 162 is attached, the chip carrier 170 is placed into a mold where conductive loaded resin-based material is then molded over the carrier to form the EMI shield 134. To operate effectively, the shield 134 should be connected to an AC ground and, more preferably, to the system ground. In this embodiment, a conductive wire 166, preferably comprising metal, is embedded into the shield 134. This wire is preferably molded into the conductive loaded resin-based material 134. The grounding wire 166 can easily be attached to the ground signal or plane of the printed wiring board (PWB) or to a chassis ground of the system. The above described embodiment may be extended to any type of chip carrier such as through-hole leaded, surface mount, flat pack, and the like. The integration of the EMI shield 134 onto the chip carrier facilitates creation of system-on-chip applications and reduces part count, tooling cost, and assembly complexity.

A particularly useful feature of the present invention is that the conductive loaded resin-based material may comprise a flexible base resin. In this case, a flexible EMI shield 134 is formed. A flexible EMI shield 134 is particularly useful for enhancing shock and vibration performance of the completed system. Prior art electronic systems feature metal EMI shields. Under severe vibration and/or shock, a metal EMI shield can pull copper cladding off the PWB or can crack solder joints. However, the flexible, conductive loaded resin-based EMI shield of the present invention absorbs part of the vibration and/or shock to thereby reduce stress and damage to the circuit board.

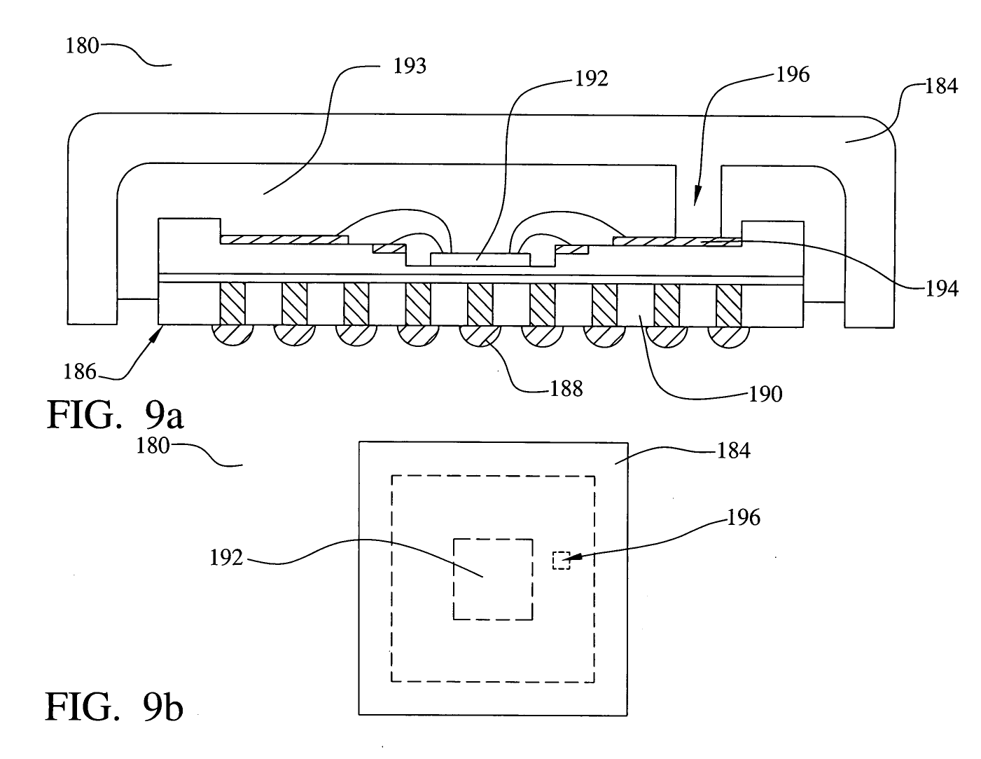

Referring now to FIGS. 9a and 9b a fourth preferred embodiment 180 of the present invention is illustrated. A plastic, ball grid array (BGA) chip carrier 180 is shown with an integrated EMI shield 184 comprising a conductive loaded resin-based material. In this case, the integrated circuit die 192 is connected to the metal traces 194 on the substrate 190 by metal wire. The ball array 188 connects to the metal traces 194 by vertical vias and/or an interconnect layer as described above. The wire bonded chip carrier assembly is then molded with an encapsulating layer 193. The encapsulating layer 192 in this case has opening(s) 196 that expose the grounding signal routed on a metal trace(s) 194 of the chip carrier 180. This opening(s) 196 is preferably formed during the molding process for the encapsulating layer 193. A conductive loaded resin-based layer 184 is then molded over the encapsulating layer 193 to form the EMI shield 184. The conductive material 184 contacts the underlying metal trace(s) 194 to thereby form a connection between the EMI shield and a grounding signal. This approach to EMI shielding further reduces assembly complexity. Again, this approach may be used with carriers of various types such as through-hole leaded, surface mount, flat-pack, ball array, and the like.

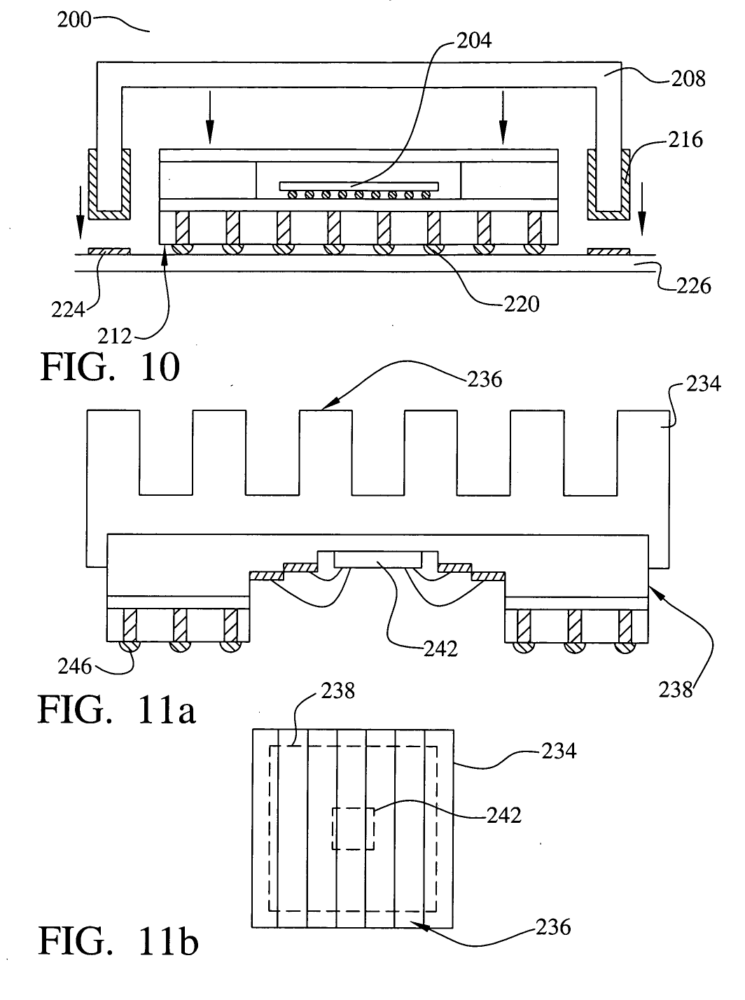

Referring now to FIG. 10, a fifth preferred embodiment 200 of the present invention is illustrated. In this case, the conductive loaded resin-based EMI shield 208 is molded separately from the chip carrier 212 and is then placed over the chip carrier 212. A ceramic, ball grid array chip carrier 212 is shown with an integrated circuit die 204 electrically connected to the ball array 220 via flip chip attachment. The EMI shield 208 is preferably formed by injection molding or by extrusion molding of the conductive loaded resin-based material. After molding, a metal layer 216 is formed on the EMI shield 208 to create a solderable layer 216 where the EMI shield 208 will contact the printed wiring board (PWB) 226. The metal layer 216 may be formed by plating or by coating. If the method of formation is metal plating, then the resin-based structural material of the conductive loaded, resin-based material is one that can be metal plated. There are very many of the polymer resins that can be plated with metal layers. For example, GE Plastics, SUPEC, VALOX, ULTEM, CYCOLAC, UGIKRAL, STYRON, CYCOLOY are a few resin-based materials that can be metal plated. The metal layer 216 may be formed by, for example, electroplating or physical vapor deposition. After the shield 208 is placed over the chip carrier 212, the shield 208 is soldered to grounding connections 224 on the PWB 226 using, for example, a solder reflow process.

Referring now to FIGS. 11a and 11b, a sixth preferred embodiment of the present invention is illustrated. A heat sink function 234 is integrated onto the chip carrier 238. In particular, an inverted plastic ball grid array chip carrier 238 is shown. In an inverted chip carrier 238, the integrated circuit die 242 is placed into the carrier 238 from the bottom side, or the side of the carrier 238 where the ball grid array (BGA) 246 is formed. In this case, the die 242 is mounted onto the substrate 239 and then is wire bonded to metal traces that are electrically connected to the ball array 246. This arrangement is particularly useful for removing heat from the circuit die using a top side heat sink since a large surface area of the die backside is contacted to the substrate 239 and then this substrate 239 contacts the overlying the heat sink 234. Preferably, the substrate 239 comprises an electrically insulating but thermally conducting material such as ceramic.

Preferably, the conductive loaded resin-based heat sink 234 is over-molded onto the top side of the carrier 238 after the chip carrier subassembly steps of mounting and wire bonding and capping the underside are completed. Alternatively, the heat sink 234 may be over-molded prior to mounting the integrated circuit die 242. The over-molding step forms a heat sink 234 that is in intimate contact with the carrier 238 such that the thermal resistance between the substrate 239 and the heat sink 234 is minimized. In addition, to improve the thermal efficiency of the system, fins or pins or other structures to maximize surface area may be molded into the heat sink 234. The excellent thermal conductivity of the conductive loaded resin-based material according to the present invention provides substantial heat transfer. Alternatively, the conductive loaded resin-based heat sink 234 may be molded separately from the chip carrier 238 and then attached to the chip carrier 238 using a conductive adhesive or interface layer such as boron nitride. As an alternative to using an adhesive, the heat sink 234 may be bonded to the chip carrier 238 using ultrasonic welding. Ultrasonic welding is particularly useful for bonding a resin-based chip carrier to the conductive loaded resin-based heat sink 234 especially if the base resin of the carrier 238 and of heat sink 234 are the same material. The integrated heat sink 234 may be applied to any type of carrier device, such as through-hole leaded, surface mount, flat-pack, ball grid array, and the like, to reduce part count, tooling costs, and assembly complexity.

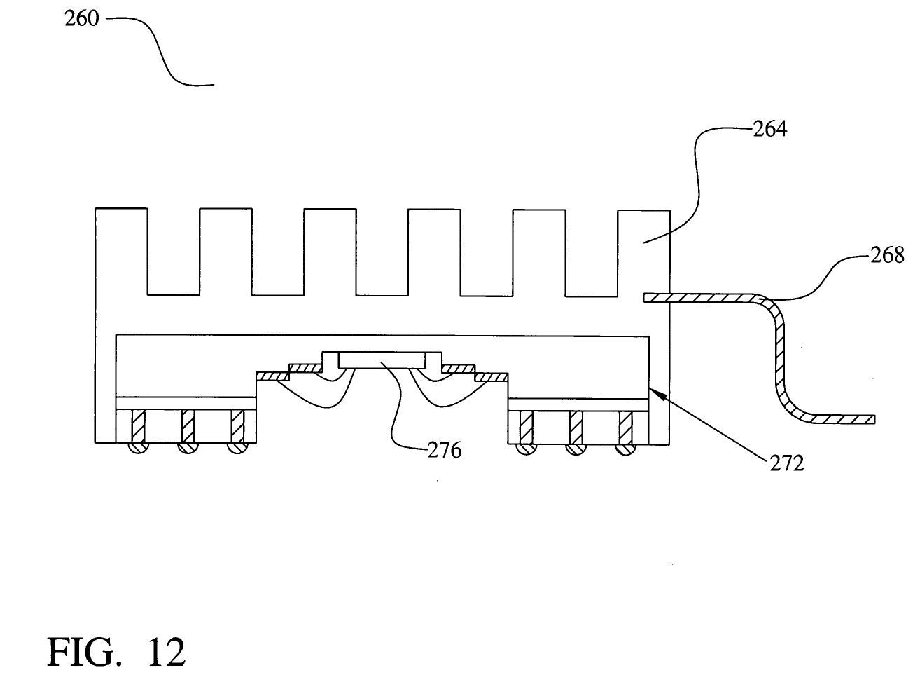

The integrated EMI shield and the heat sink are similar structures that may be combined to form a combined heat sink/EMI shield. Referring now to FIG. 12, a seventh preferred embodiment of the present invention shows an inverted ball grid array (BGA) chip carrier 272 with a combined integrated heat sink and EMI shield 264 comprising a conductive loaded resin-based material. This combined heat sink and EMI shield 264 may be molded onto the chip carrier 272 either before or after mounting and wire-bonding the integrated circuit die. Preferably, the die 276 is mounted, wire-bonded, and sealed prior to over-molding the conductive loaded resin-based material 264. A grounding wire 268 is molded into the heat sink/EMI shield 264 to provide a connection point to the system ground plane.

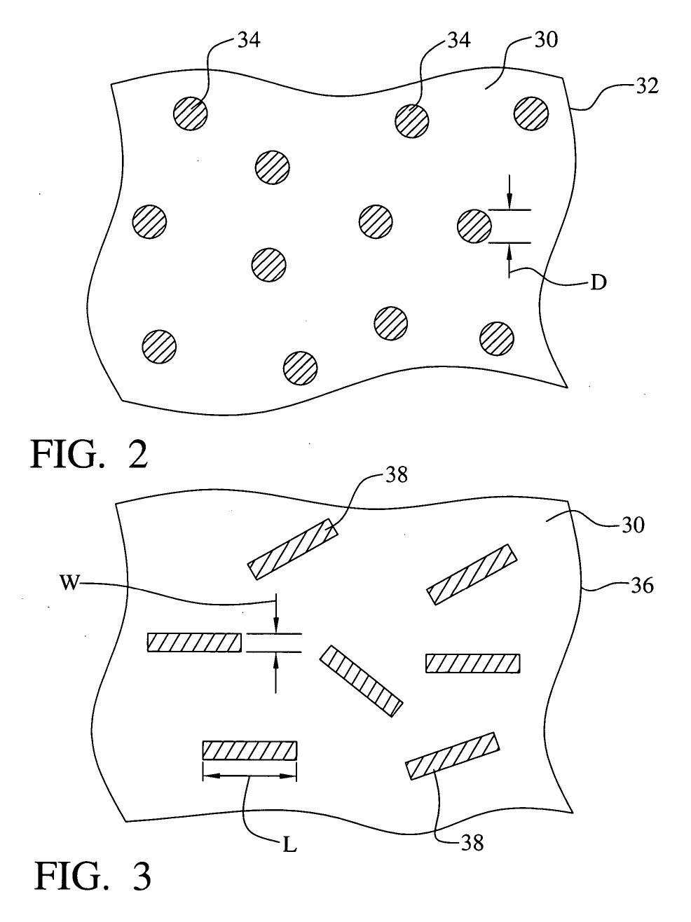

The conductive loaded resin-based material typically comprises a micron powder(s) of conductor particles and/or in combination of micron fiber(s) homogenized within a base resin host. FIG. 2 shows cross section view of an example of conductor loaded resin-based material 32 having powder of conductor particles 34 in a base resin host 30. In this example the diameter D of the conductor particles 34 in the powder is between about 3 and 12 microns.

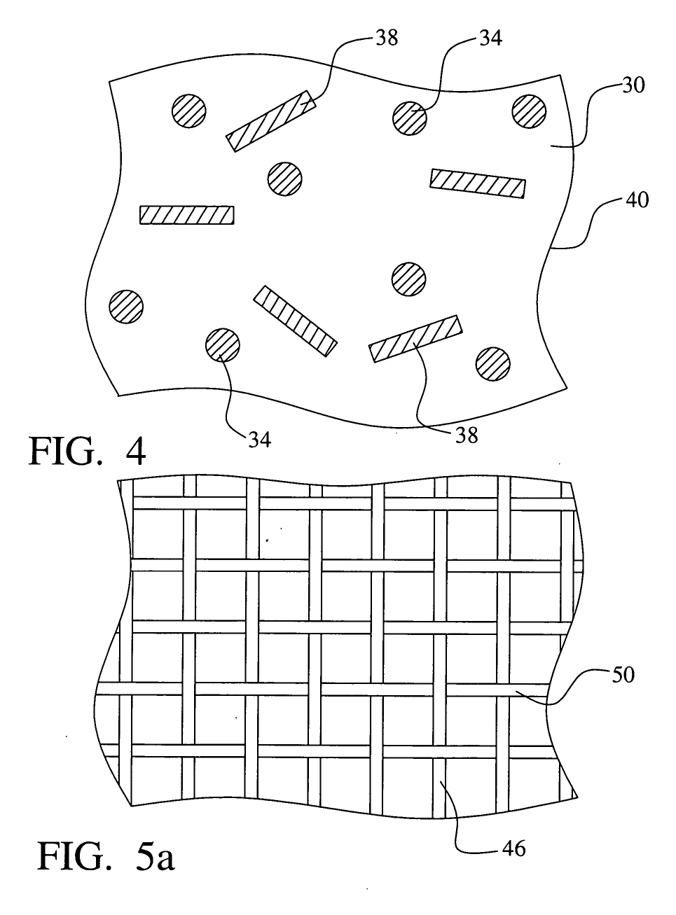

FIG. 3 shows a cross section view of an example of conductor loaded resin-based material 36 having conductor fibers 38 in a base resin host 30. The conductor fibers 38 have a diameter of between about 3 and 12 microns, typically in the range of 10 microns or between about 8 and 12 microns, and a length of between about 2 and 14 millimeters. The conductors used for these conductor particles 34 or conductor fibers 38 can be stainless steel, nickel, copper, silver, or other suitable metals or conductive fibers, or combinations thereof. These conductor particles and or fibers are homogenized within a base resin. As previously mentioned, the conductive loaded resin-based materials have a resistivity between about 5 and 25 ohms per square, other resistivities can be achieved by varying the doping parameters and/or resin selection. To realize this resistivity the ratio of the weight of the conductor material, in this example the conductor particles 34 or conductor fibers 38, to the weight of the base resin host 30 is between about 0.20 and 0.40, and is preferably about 0.30. Stainless Steel Fiber of 8-11 micron in diameter and lengths of 4-6 mm with a fiber weight to base resin weight ratio of 0.30 will produce a very highly conductive parameter, efficient within any EMF spectrum. Referring now to FIG. 4, another preferred embodiment of the present invention is illustrated where the conductive materials comprise a combination of both conductive powders 34 and micron conductive fibers 38 homogenized together within the resin base 30 during a molding process.

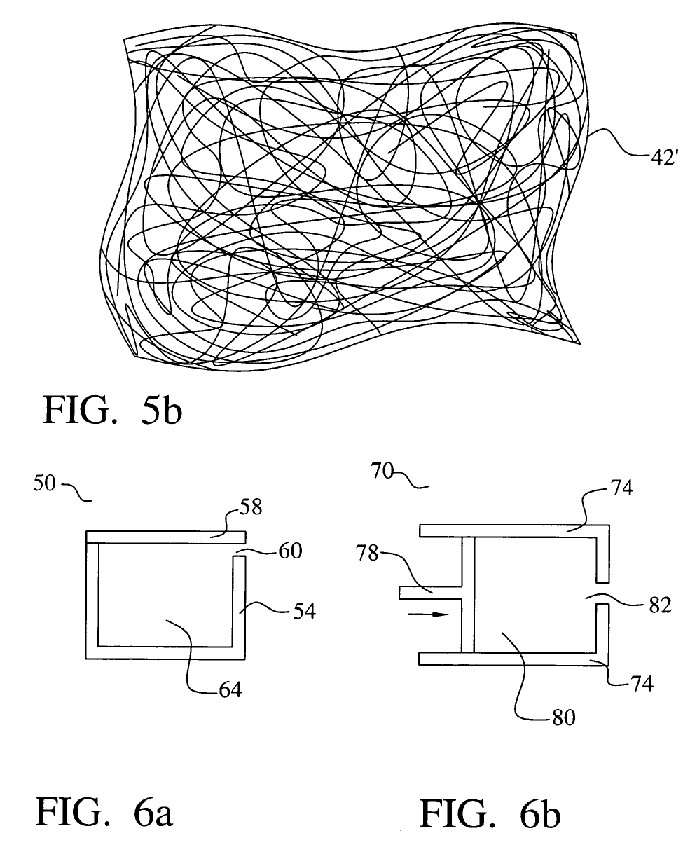

Referring now to FIGS. 5a and 5b, a preferred composition of the conductive loaded, resin-based material is illustrated. The conductive loaded resin-based material can be formed into fibers or textiles that are then woven or webbed into a conductive fabric. The conductive loaded resin-based material is formed in strands that can be woven as shown. FIG. 5a shows a conductive fabric 42 where the fibers are woven together in a two-dimensional weave 46 and 50 of fibers or textiles. FIG. 5b shows a conductive fabric 42′ where the fibers are formed in a webbed arrangement. In the webbed arrangement, one or more continuous strands of the conductive fiber are nested in a random fashion. The resulting conductive fabrics or textiles 42, see FIG. 5a, and 42′, see FIG. 5b, can be made very thin, thick, rigid, flexible or in solid form(s).

Similarly, a conductive, but cloth-like, material can be formed using woven or webbed micron stainless steel fibers, or other micron conductive fibers. These woven or webbed conductive cloths could also be sandwich laminated to one or more layers of materials such as Polyester(s), Teflon(s), Kevlar(s) or any other desired resin-based material(s). This conductive fabric may then be cut into desired shapes and sizes.

Integrated chip carrier functions formed from conductive loaded resin-based materials can be formed or molded in a number of different ways including injection molding, extrusion or chemically induced molding or forming. FIG. 6a shows a simplified schematic diagram of an injection mold showing a lower portion 54 and upper portion 58 of the mold 50. Conductive loaded blended resin-based material is injected into the mold cavity 64 through an injection opening 60 and then the homogenized conductive material cures by thermal reaction. The upper portion 58 and lower portion 54 of the mold are then separated or parted and the structures are removed.

FIG. 6b shows a simplified schematic diagram of an extruder 70 for forming integrated chip carrier functions using extrusion. Conductive loaded resin-based material(s) is placed in the hopper 80 of the extrusion unit 74. A piston, screw, press or other means 78 is then used to force the thermally molten or a chemically induced curing conductive loaded resin-based material through an extrusion opening 82 which shapes the thermally molten curing or chemically induced cured conductive loaded resin-based material to the desired shape. The conductive loaded resin-based material is then fully cured by chemical reaction or thermal reaction to a hardened or pliable state and is ready for use.

The advantages of the present invention may now be summarized. An effective integrated circuit chip carrier is achieved. A method to form an integrated circuit chip carrier with integrated functions molded of conductive loaded resin-based materials is achieved. A chip carrier with an integrated antenna molded of conductive loaded resin-based material is realized. A chip carrier with an integrated heat sink molded of conductive loaded resin-based material is realized. A chip carrier with an integrated EMI shield molded of conductive loaded resin-based material is realized. A chip carrier with a combined integrated heat sink and EMI shield molded of conductive loaded resin-based material is achieved. The methods of forming chip carriers with integrated functions molded of conductive loaded resin-based material are compatible with a variety of chip carrier types.

As shown in the preferred embodiments, the novel methods and devices of the present invention provide an effective and manufacturable alternative to the prior art.

While the invention has been particularly shown and described with reference to the preferred embodiments thereof, it will be understood by those skilled in the art that various changes in form and details may be made without departing from the spirit and scope of the invention.

What is claimed is:

1. An integrated circuit device comprising:
a chip carrier with an integrated circuit die fixably attached to said chip carrier; and
an antenna structure molded onto said chip carrier and comprising a conductive loaded, resin-based material comprising conductive materials in a base resin host.

2. The device according to claim 1 wherein the ratio, by weight, of said conductive materials to said resin host is between about 0.20 and about 0.40.

3. The device according to claim 1 wherein said conductive materials comprise metal powder.

4. The device according to claim 3 wherein said metal powder is nickel, copper, or silver.

5. The device according to claim 3 wherein said metal powder is a non-conductive material with a metal plating.

6. The device according to claim 5 wherein said metal plating is nickel, copper, silver, or alloys thereof.

7. The device according to claim 3 wherein said metal powder comprises a diameter of between about 3 μm and about 12 μm.

8. The device according to claim 1 wherein said conductive materials comprise non-metal powder.

9. The device according to claim 8 wherein said non-metal powder is carbon, graphite, or an amine-based material.

10. The device according to claim 1 wherein said conductive materials comprise a combination of metal powder and non-metal powder.

11. The device according to claim 1 wherein said conductive materials comprise micron conductive fiber.

12. The device according to claim 11 wherein said micron conductive fiber is nickel plated carbon fiber, stainless steel fiber, copper fiber, silver fiber or combinations thereof.

13. The device according to claim 11 wherein said micron conductive fiber has a diameter of between about 3 μm and about 12 μm and a length of between about 2 mm and about 14 mm.

14. The device according to claim 1 wherein said conductive materials comprise a combination of conductive powder and conductive fiber.

15. The device according to claim 1 wherein said antenna structure is electrically connected to said integrated circuit die.

16. The device according to claim 15 wherein said electrical connection is by direct contact between said conductive loaded resin-based material and metal interconnects on a substrate within said chip carrier.

17. The device according to claim 15 wherein said electrical connection is by direct contact between said conductive loaded resin-based material and external leads of said chip carrier.

18. The device according to claim 15 further comprising an encapsulating layer between said integrated circuit die and said antenna structure.

19. The device according to claim 15 wherein said electrically contacting is through an opening in said encapsulating layer.

20. An integrated circuit device comprising:
a chip carrier with an integrated circuit die fixably attached to said chip carrier; and
an EMI shield on said chip carrier and comprising a conductive loaded, resin-based material comprising conductive materials in a base resin host.

21. The device according to claim 20 wherein the ratio, by weight, of said conductive materials to said resin host is between about 0.20 and about 0.40.

22. The device according to claim 20 wherein said conductive materials comprise metal powder.

23. The device according to claim 22 wherein said metal powder is nickel, copper, or silver.

24. The device according to claim 20 wherein said metal powder is a non-conductive material with a metal plating.

25. The device according to claim 24 wherein said metal plating is nickel, copper, silver, or alloys thereof.

26. The device according to claim 23 wherein said metal powder comprises a diameter of between about 3 μm and about 12 μm.

27. The device according to claim 20 wherein said conductive materials comprise non-metal powder.

28. The device according to claim 27 wherein said non-metal powder is carbon, graphite, or an amine-based material.

29. The device according to claim 20 wherein said conductive materials comprise a combination of metal powder and non-metal powder.

30. The device according to claim 20 wherein said conductive materials comprise micron conductive fiber.

31. The device according to claim 30 wherein said micron conductive fiber is nickel plated carbon fiber, stainless steel fiber, copper fiber, silver fiber or combinations thereof.

32. The device according to claim 30 wherein said micron conductive fiber has a diameter of between about 3 μm and about 12 μm and a length of between about 2 mm and about 14 mm.

33. The device according to claim 20 wherein said conductive materials comprise a combination of conductive powder and conductive fiber.

34. The device according to claim 20 wherein said EMI shield is electrically connected to said integrated circuit die.

35. The device according to claim 34 wherein said electrical connection is by direct contact between said conductive loaded resin-based material and metal interconnects on a substrate in said chip carrier.

36. The device according to claim 34 wherein said electrical connection is by direct contact between said conductive loaded resin-based material and external leads of said chip carrier.

37. The device according to claim 34 further comprising an encapsulating layer between said integrated circuit die and said antenna structure.

38. The device according to claim 34 wherein said electrically contacting is through an opening in said encapsulating layer.

39. The device according to claim 20 further comprising a conductive wire molded into said EMI shield.

40. The device according to claim 20 wherein said EMI shield is molded onto said chip carrier.

41. The device according to claim 20 wherein said EMI shield further comprises a solderable layer of metal.

42. An integrated circuit device comprising:
a chip carrier with an integrated circuit die fixably attached to said chip carrier; and
a heat sink on said chip carrier and comprising a conductive loaded, resin-based material comprising conductive materials in a base resin host.

43. The device according to claim 42 wherein the ratio, by weight, of said conductive materials to said resin host is between about 0.20 and about 0.40.

44. The device according to claim 42 wherein said conductive materials comprise metal powder.

45. The device according to claim 44 wherein said metal powder is nickel, copper, or silver.

46. The device according to claim 44 wherein said metal powder is a non-conductive material with a metal plating.

47. The device according to claim 46 wherein said metal plating is nickel, copper, silver, or alloys thereof.

48. The device according to claim 44 wherein said metal powder comprises a diameter of between about 3 μm and about 12 μm.

49. The device according to claim 42 wherein said conductive materials comprise non-metal powder.

50. The device according to claim 49 wherein said non-metal powder is carbon, graphite, or an amine-based material.

51. The device according to claim 42 wherein said conductive materials comprise a combination of metal powder and non-metal powder.

52. The device according to claim 42 wherein said conductive materials comprise micron conductive fiber.

53. The device according to claim 52 wherein said micron conductive fiber is nickel plated carbon fiber, stainless steel fiber, copper fiber, silver fiber or combinations thereof.

54. The device according to claim 52 wherein said micron conductive fiber has a diameter of between about 3 μm and about 12 μm and a length of between about 2 mm and about 14 mm.

55. The device according to claim 42 wherein said conductive materials comprise a combination of conductive powder and conductive fiber.

56. The device according to claim 42 wherein said heat sink is molded onto said chip carrier.

57. The device according to claim 42 further comprising a conductive wire molded into said heat sink.

58. The device according to claim 42 wherein heat sink further comprises fins or pins to increase surface area.

59. The device according to claim 42 wherein said heat sink is connected to a ground signal to form a simultaneous EMI shielding function.

60. The device according to claim 42 wherein said heat sink is bonded onto said chip carrier with an adhesive.

61. The device according to claim 42 wherein said heat sink is bonded onto said chip carrier by ultrasonic welding.

62. A method to form an integrated circuit device, said method comprising:
providing a chip carrier with an integrated circuit die fixably attached to said chip carrier;
providing a conductive loaded, resin-based material comprising conductive materials in a resin-based host; and
molding said conductive loaded, resin-based material to form an integrated antenna, heat sink, or EMI shield on said chip carrier.

63. The method according to claim 62 wherein the ratio, by weight, of said conductive materials to said resin host is between about 0.20 and about 0.40.

64. The method according to claim 62 wherein the conductive materials comprise a conductive powder.

65. The method according to claim 62 wherein said conductive materials comprise a micron conductive fiber.

66. The method according to claim 62 wherein said conductive materials comprise a combination of conductive powder and conductive fiber.

67. The method according to claim 62 wherein said molding comprises:
placing said chip carrier into a mold;
injecting said conductive loaded, resin-based material into a mold;
curing said conductive loaded, resin-based material; and
removing said chip carrier with said integrated antenna, heat sink, or shield from said mold.

68. The method according to claim 62 further comprising forming an encapsulating layer between said chip carrier and said integrated antenna, heat sink, or shield.

69. The method according to claim 62 wherein said molding comprises:
loading said conductive loaded, resin-based material into a chamber;
extruding said conductive loaded, resin-based material out of said chamber through a shaping outlet; and
curing said conductive loaded, resin-based material to form said integrated antenna, heat sink, or EMI shield.

70. The method according to claim 69 further comprising attaching said antenna, heat sink, or EMI shield to said chip carrier.

71. The method according to claim 70 wherein said step of attaching is by an adhesive.

72. The method according to claim 70 wherein said step of attaching is by an ultrasonic welding.
